(19) United States
(12) Patent Application Publication
(10) Pub. No.: US 2004/0004277 A1
(43) Pub. Date: Jan. 8, 2004

(54) Semiconductor package with reinforced substrate and fabrication method of the substrate

(76) Inventors: Chung-Che Tsai, Hsinchu (TW); Jin-Chuan Bai, Hsinchu (TW); Huan-Ping Su, Hsinchu (TW)

Correspondence Address: ANDERSON KILL & OLICK, P.C., 1251 Avenue of the Americas, New York, NY, 10020-1182, US

(21) Appl. No.: 10/314,065

(22) Filed: Dec. 5, 2002

(30) Foreign Application Priority Data
Jul. 3, 2002 (TW) 91114735

(51) Int. Cl. H01L 23/02

(52) U.S. Cl. 257/678

(57) ABSTRACT

A semiconductor package with a reinforced substrate and a fabrication method of the substrate are provided. The substrate is formed of a metal core layer with relatively high rigidity, and an insulating layer is coated on at least a surface of the core layer. At least a ground via is formed through the insulating layer, allowing a chip mounted on the substrate to be electrically connected and grounded to the substrate by the ground via. The reinforced substrate provides the semiconductor package with sufficient mechanical strength, and can be reduced in thickness in favor of package profile miniaturization. Moreover, the substrate made of the metal core layer and insulating layer has a relatively small dielectric constant to facilitate electron transmission velocity, thereby improving electrical quality of the semiconductor package. Furthermore, the metal core layer is made of a thermally-conductive metallic material, and enhances heat dissipating efficiency of the semiconductor package.

### FIELD OF THE INVENTION

The present invention relates to semiconductor packages and fabrication methods of substrates used in the semiconductor packages, and more particularly, to a semiconductor package with a reinforced substrate, and a method for fabricating the substrate.

### BACKGROUND OF THE INVENTION

A conventional substrate for use in a semiconductor package is fabricated by preparing a core layer made of fiber glass and resin, and then attaching a copper film to at least a surface of the core layer, allowing the copper film to be patterned by photo-resist covering, exposing, developing and etching processes to form predetermined conductive traces, or a printing process is implemented to directly print predetermined copper-made conductive traces and bond pads on the surface of the core layer. Such a fabricated substrate can be readily subject to subsequent chip-bonding, wire-bonding and ball-implantation processes to form a semiconductor package.

However, the above conventional substrate has significant drawbacks. For example, the core layer of the substrate is made of fiber glass and resin that are poor in rigidity, during assembly of the semiconductor package, it easily leads to deformation or cracks of the substrate, and thus damages quality and yield of fabricated products. Accordingly, the substrate is usually made with increased thickness to provide sufficient mechanical strength for the semiconductor package, which thereby enlarges package size and is not favored for profile miniaturization of package products. Moreover, the substrate with the core layer made of fiber glass and resin has a larger dielectric constant; as electronic transmission velocity is inversely proportional to the dielectric constant, the larger the dielectric constant of the substrate, the smaller the electronic transmission velocity is; this would increase electronic interference and degrade electric quality of the semiconductor package.

Therefore, the problem to be solved is to provide a substrate or a semiconductor package with the substrate for resolving the above drawbacks, so as to effectively improve mechanical strength and electric quality of the semiconductor package.

### SUMMARY OF THE INVENTION

An objective of the present invention is to provide a semiconductor package with a reinforced substrate and a fabrication method of the substrate, which can enhance mechanical strength of the semiconductor package through the use of the substrate.

Another objective of the invention is to provide a semiconductor package with a reinforced substrate and a fabrication method of the substrate, which can decrease a dielectric constant of the substrate and increase electronic transmission velocity, so as to improve electric quality of the semiconductor package.

A further objective of the invention is to provide a semiconductor package with a reinforced substrate and a fabrication method of the substrate, which can reduce thickness of the substrate and overall the semiconductor package.

A further objective of the invention is to provide a semiconductor package with a reinforced substrate and a fabrication method of the substrate, which can enhance heat-dissipating efficiency of the semiconductor package.

In accordance with the above and other objectives, the present invention proposes a semiconductor package with a reinforced substrate and a fabrication method of the substrate. The semiconductor package comprises: at feast a chip formed with a plurality of bond pads at predetermined positions on a surface thereof; a substrate formed with at least an opening penetrating through the substrate, and having a metal core layer with an insulating layer being respectively applied on an upper surface and a lower surface of the metal core layer, so as to allow the chip to be mounted to the insulating layer on the upper surface of the metal core layer in a manner as to expose the bond pads of the chip to the opening, wherein the insulating layer on the lower surface of the metal core layer is formed with a plurality of ground vias penetrating through the insulating layer to thereby partly expose the lower surface of the metal core layer to the ground vias, and wherein the insulating layer on the lower surface of the metal core layer is formed with a plurality of conductive traces, first pads and second pads; a solder mask layer applied on the insulating layer formed on the lower surface of the metal core layer, for covering the conductive traces but exposing the ground vias, first pads and second pads; a plurality of first conductive elements for electrically connecting the bond pads of the chip to the first pads, and for electrically connecting the first pads to exposed part of the lower surface of the metal core layer, so as to allow the chip to be electrically connected and grounded to the substrate by the first conductive elements; an encapsulant for encapsulating the opening of the substrate, the ground vias and the first conductive elements; and a plurality of second conductive elements implanted at the second pads, for electrically connecting the chip to an external device.

A fabrication method of the substrate used in the above semiconductor package comprises the steps of: preparing a metal core layer; applying an insulating layer on at least a surface of the metal core layer; and forming a plurality of conductive traces on the insulating layer, and forming a plurality of ground vias through the insulating layer, so as to partly expose the surface of the metal core layer to the ground vias.

Another embodiment for the fabrication method of the substrate comprises the steps of: preparing a metal core layer; applying an insulating layer attached with a copper film on at least a surface of the metal core layer, allowing the insulating layer to be interposed between the metal core layer and the copper film; and patterning the copper film to form a plurality of conductive traces, and forming a plurality of ground vias through the insulating layer, so as to partly expose the surface of the metal core layer to the ground vias.

The metal core layer of the substrate is made of copper or copper alloy, and the insulating layer formed on the metal core layer is made of a resin compound or fiber glass.

The above semiconductor package with a substrate made of a metal core layer and at least an insulating layer can provide significant benefits. First, the substrate formed by the metal core layer with relatively high rigidity may enhance mechanical strength of the substrate and entire the semiconductor package, such that the substrate can be thinned but provide desirable structural strength, thereby effectively reducing thickness of the substrate and the semiconductor package. Moreover, the substrate formed by the metal core layer and insulating layer has a relatively small dielectric constant; as electronic transmission velocity is inversely proportional to the dielectric constant, the substrate with a small dielectric constant would increase the electronic transmission velocity and reduce electronic interference, thereby improving electric quality of the semiconductor package. Furthermore, the substrate is formed with a plurality of ground vias that partly expose the metal core layer, allowing a chip mounted on the substrate to be electrically connected to exposed part of the metal core layer and thus to be grounded; therefore, the metal core layer of the substrate also provides grounding effect for the chip. And, the metal core layer is made of a thermally-conductive metallic material such as copper or copper alloy, and enhances heat dissipating efficiency of the semiconductor package.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a semiconductor package with a reinforced substrate according to the invention;

FIG. 2 is a bottom view of FIG. 1 showing electrical connection of bonding wires;

FIGS. 3A-3E are schematic diagrams showing fabrication processes for a semiconductor package with a reinforced substrate according to the invention; and

FIGS. 4A and 4B are schematic diagrams respectively showing fabrication processes for a reinforced substrate according to the invention.

### DETAILED DESCRIPTION OF THE PREFERRED EMBODIMENTS

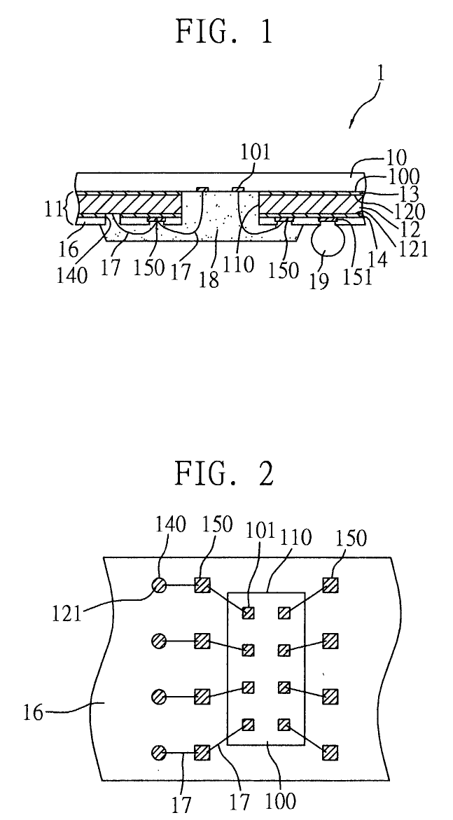

Preferred embodiments for a semiconductor package with a reinforced substrate proposed in the present invention are described in more detail as follows with reference to FIGS. 1 to 4.

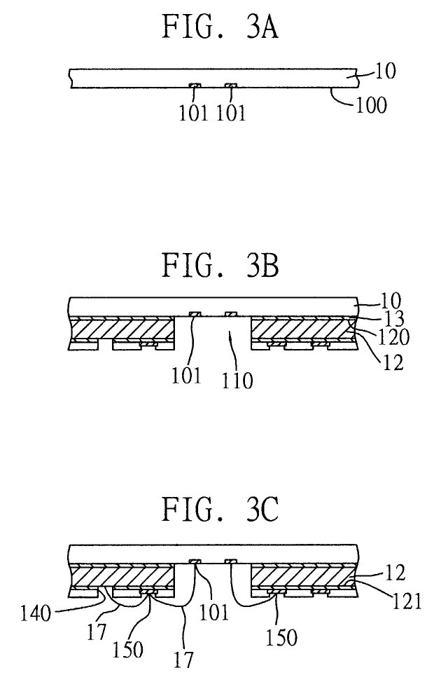

FIGS. 1 and 2 illustrate a semiconductor package 1 according to the invention. As shown in the drawings, this semiconductor package 1 comprises: at least a chip 10 formed with a plurality of bond pads 101 at predetermined positions on a surface 100 thereof; a substrate 11 formed with at least an opening 110 penetrating through the substrate 11, and having a metal core layer 12 with an insulating layer 13, 14 being respectively applied on an upper surface 120 and an lower surface 121 of the metal core layer 12, so as to allow the chip 10 to be mounted to the insulating layer 13 on the upper surface 120 of the metal core layer 12 in a manner as to expose the bond pads 101 of the chip 10 to the opening 110, wherein the insulating layer 14 on the lower surface 121 of the metal core layer 12 is formed with a plurality of ground vias 140 penetrating through the insulating layer 14 to thereby partly expose the lower surface 121 of the metal core layer 12 to the ground vias 140, and wherein the insulating layer 14 on the lower surface 121 of the metal core layer 12 is formed with a plurality of conductive traces (not shown), bond fingers 150 and ball pads 151; a solder mask layer 16 applied on the insulating layer 14 formed on the lower surface 121 of the metal core layer 12, for covering the conductive traces but exposing the ground vias 140, bond fingers 150 and ball pads 151; a plurality of bonding wires 17 for electrically connecting the bond pads 101 of the chip 10 to the bond fingers 150, and for electrically connecting the bond fingers 150 to exposed part of the lower surface 121 of the metal core layer 12, so as to allow the chip 10 to be electrically connected and grounded to the substrate 11 by the bonding wires 17; an encapsulant 18 for encapsulating the opening 110 of the substrate II, the ground vias 140 and the bonding wires 17; and a plurality of solder balls 19 implanted at the ball pads 151, for electrically connecting the chip 10 to an external device such as a printed circuit board (not shown).

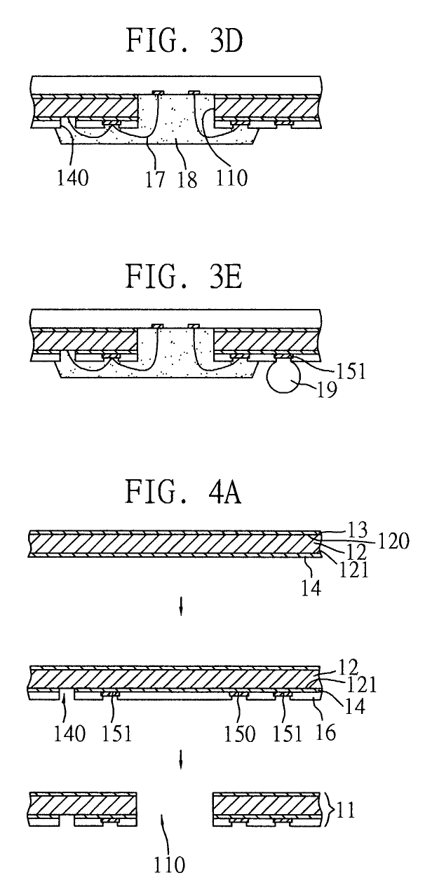

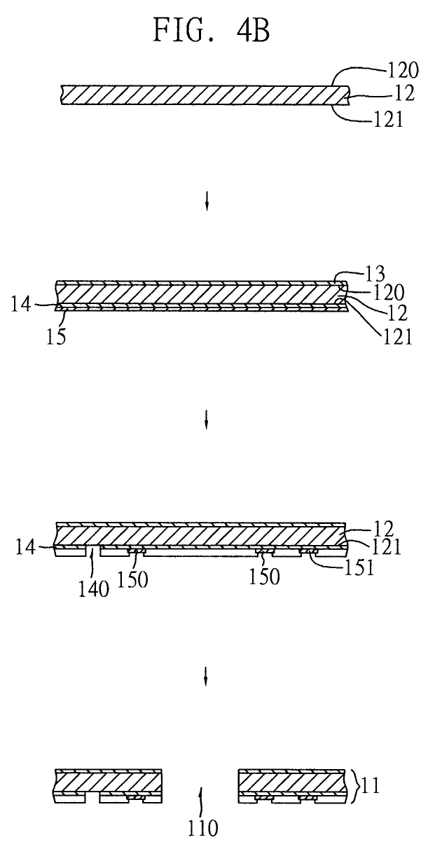

The above semiconductor package 1 and substrate 11 can be fabricated by process steps illustrated in FIGS. 3A-3E and FIGS. 4A and 4B respectively.

Referring to FIG. 3A, the first step is to prepare a chip 10 formed with a plurality of bond pads 101 at predetermined positions on a surface 100 thereof. Fabrication of the chip 10 employs conventional technology and is thereby not to be further described herein.

Referring to FIG. 3B, the next step is to prepare a substrate 11 formed by a metal core layer 12, and then to mount the surface 100 of the chip 10 on the substrate 11. The substrate 11 can be fabricated by the procedural step shown in FIG. 4A or 4B as detailed below.

As shown in FIG. 4A, it is firstly to prepare a metal core layer 12 made of copper or copper alloy, the metal core layer 12 having an upper surface 120 and a lower surface 121 opposed to the upper surface 120. An insulating layer 13, 14 is respectively applied on the upper surface 120 and the lower surface 121 of the metal core layer 12; the insulating layer 13, 14 may be made of a resin compound or fiber glass. Then, the insulating layer 14 on the lower surface 121 of the metal core layer 12 is formed with a plurality of conductive traces (not shown), bond fingers 150 and ball pads 151, and with a plurality of ground vias 140 penetrating through the insulating layer 14 to thereby partly expose the lower surface 121 of the metal core layer 12 to the ground vias 140. The conductive traces, bond fingers 150 and ball pads 151 may be fabricated by patterning a copper film 15 attached to the insulating layer 14, or may be directly printed on the insulating layer 14. Thereafter, a solder mask layer 16 is applied on the insulating layer 14, for covering the conductive traces but exposing the bond fingers 150, ball pads 151 and ground vias 140. Finally, an opening 110 is formed through the substrate 11 at a position corresponding to the bond pads 101 of the chip 10.

FIG. 4B illustrates another embodiment of a fabrication method of the substrate 11. The first step is to form a metal core layer 12 having an upper surface 120 and a lower surface 121 opposed to the upper surface 120. Next, an insulating layer 13 is coated on the upper surface 120 of the metal core layer 12, and an insulating layer 14 attached with a copper film 15 is applied on the lower surface 121 of the metal core layer 12 in a manner as to interpose the insulating layer 14 between the metal core layer 12 and the copper film 15. Then, the copper film 15 is patterned to form a plurality of conductive traces (not shown), bond fingers 150 and ball pads 151, and the insulating layer 14 is formed with a plurality of ground vias 140 penetrating through the insulating layer 14 to thereby partly expose the lower surface 121 of the metal core layer 12 to the ground vias 140. Thereafter, a solder mask layer 16 is applied on the insulating layer 14, for covering the conductive traces but exposing the bond fingers 150, ball pads 151 and ground vias 140. Finally, an opening 110 is formed through the substrate 11 at a position corresponding to the bond pads 101 of the chip 10.

With the substrate 11 being fabricated as above, the chip 10 can be mounted to the insulating layer 13 on the upper surface 120 of the metal core layer 12, with the bond pads 101 of the chip 10 being exposed to the opening 110 of the substrate 11, as shown in FIG. 3B.

Referring to FIG. 3C, a wire-bonding process is performed to form a plurality of bonding wires 17 such as gold wires. The bonding wires 17 are used to electrically connect the bond pads 101 of the chip 10 to the bond fingers 150, and to electrically connect the bond fingers 150 to exposed part of the lower surface 121 of the metal core layer 12, so as to allow the chip 10 to be electrically connected and grounded to the substrate 11 by the bonding wires 17.

Referring to FIG. 3D, a molding process is performed to form an encapsulant 18 that encapsulates the opening 110 of the substrate 11, the ground vias 140 and the bonding wires 17.

Finally, referring to FIG. 3E, a ball-implantation process is performed to implant a plurality of solder balls 19 at the ball pads 151, allowing the semiconductor package 1 and the chip 10 to be electrically connected to an external device such as a printed circuit board (not shown) by the solder balls 19.

The above wire-bonding, molding and ball-implantation processes are conventional and thereby not to be further detailed herein. This therefore completes fabrication of the semiconductor package 1.

In conclusion, the above semiconductor package with a substrate made of a metal core layer and insulating layers can provide significant benefits. First, the substrate formed by the metal core layer with relatively high rigidity may enhance mechanical strength of the substrate and entire the semiconductor package, such that the substrate can be thinned but provide desirable structural strength, thereby effectively reducing thickness of the substrate and the semiconductor package. Moreover, the substrate formed by the metal core layer and insulating layers has a relatively small dielectric constant; as electronic transmission velocity is inversely proportional to the dielectric constant, the substrate with a small dielectric constant would increase the electronic transmission velocity and reduce electronic interference, thereby improving electric quality of the semiconductor package. Furthermore, the substrate is formed with a plurality of ground vias that partly expose the metal core layer, allowing a chip mounted on the substrate to be electrically connected to exposed part of the metal core layer and thus to be grounded; therefore, the metal core layer of the substrate also provides grounding effect for the chip. And, the metal core layer is made of a thermally-conductive metallic material such as copper or copper alloy, and enhances heat dissipating efficiency of the semiconductor package.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package with a reinforced substrate, comprising:
at least a chip formed with a plurality of bond pads at predetermined positions on a surface thereof;
a substrate formed with at least an opening penetrating through the substrate, and having a metal core layer with an insulating layer being respectively applied on an upper surface and a lower surface of the metal core layer, so as to allow the chip to be mounted to the insulating layer on the upper surface of the metal core layer in a manner as to expose the bond pads of the chip to the opening, wherein the insulating layer on the lower surface of the metal core layer is formed with a plurality of ground vias penetrating through the insulating layer to thereby partly expose the lower surface of the metal core layer to the ground vias, and wherein the insulating layer on the lower surface of the metal core layer is formed with a plurality of conductive traces, first pads and second pads;
a plurality of first conductive elements for electrically connecting the bond pads of the chip to the first pads, and for electrically connecting the first pads to exposed part of the lower surface of the metal core layer, so as to allow the chip to be electrically connected and grounded to the substrate by the first conductive elements;
an encapsulant for encapsulating the opening of the substrate, the ground vias and the first conductive elements; and
a plurality of second conductive elements implanted on the second pads, for electrically connecting the chip to an external device.

2. The semiconductor package of claim 1, further comprising: a solder mask layer applied on the insulating layer formed on the lower surface of the metal core layer, for covering the conductive traces but exposing the ground vias, first pads and second pads.

3. The semiconductor package of claim 1, wherein the bond pads are situated at central positions on the surface of the chip.

4. The semiconductor package of claim 1, wherein the metal core layer is made of a material selected from the group consisting of copper and copper alloy.

5. The semiconductor package of claim 1, wherein the insulating layer is made of a resin compound.

6. The semiconductor package of claim 1, wherein the insulating layer is made of fiber glass.

7. The semiconductor package of claim 1, wherein the conductive traces, first pads and second pads are made of copper.

8. The semiconductor package of claim 1, wherein the first conductive elements are bonding wires.

9. The semiconductor package of claim 1, wherein the second conductive elements are solder balls.

10. A fabrication method of a reinforced substrate, comprising the steps of:
preparing a metal core layer;
applying an insulating layer on at least a surface of the metal core layer; and
forming a plurality of conductive traces on the insulating layer, and forming a plurality of ground vias through the insulating layer, so as to partly expose the surface of the metal core layer to the ground vias.

11. The fabrication method of claim 10, wherein the metal core layer is made of a material selected from the group consisting of copper and copper alloy.

12. The fabrication method of claim 10, wherein the insulating layer is made of a resin compound.

13. The fabrication method of claim 10, wherein the insulating layer is made of fiber glass.

14. The fabrication method of claim 10, wherein the conductive traces are made of copper.

15. The fabrication method of claim 14, wherein the conductive traces are fabricated by patterning a copper film attached to the insulating layer.

16. The fabrication method of claim 14, wherein the conductive traces are printed on the insulating layer.

17. A fabrication method of a reinforced substrate, comprising the steps of:
preparing a metal core layer;
applying an insulating layer attached with a copper film on at least a surface of the metal core layer, allowing the insulating layer to be interposed between the metal core layer and the copper film; and
patterning the copper film to form a plurality of conductive traces, and forming a plurality of ground vias through the insulating layer, so as to partly expose the surface of the metal core layer to the ground vias.

18. The fabrication method of claim 17, wherein the metal core layer is made of a material selected from the group consisting of copper and copper alloy.

19. The fabrication method of claim 17, wherein the insulating layer is made of a resin compound.

20. The fabrication method of claim 17, wherein the insulating layer is made of fiber glass.
